(19) United States
(12) Patent Application Publication
(10) Pub. No.: US 2009/0123648 A1
(43) Pub. Date: May 14, 2009

(54) DIAMOND-DIAMOND COMPOSITES

(76) Inventor: David J. Rowcliffe, Los Osos, CA (US)

Correspondence Address: PATTERSON & SHERIDAN, L.L.P., 3040 POST OAK BOULEVARD, SUITE 1500, HOUSTON, TX, 77056, US

(21) Appl. No.: 11/910,391

(22) PCT Filed: Mar. 29, 2006
(86) PCT No.: PCT/US2006/011389

§ 371 Date: Jun. 18, 2008

Related U.S. Application Data
(60) Provisional application No. 60/667,009, filed on Mar. 31, 2005.
(60) Provisional application No. 60/676,636, filed on Apr. 29, 2005.

(51) Int. Cl. C23C 16/27; C23C 16/44

(52) U.S. Cl. 427/249.2; 427/249.8

(57) ABSTRACT

A method and apparatus for forming polycrystalline diamond composites comprising forming a preform shape with at least 60 volume percent diamond, and then depositing diamond by chemical vapor methods. The chemical vapor deposition may be chemical vapor infiltration with a thermal gradient applied through a thickness of the preform shape. The thermal gradient may be selected to provide sufficient temperature variation to produce a diamond layer on a hot surface of the preform shape but is too low to produce a diamond layer on a hot surface of the preform shape but is too low to produce a diamond layer on a cooler surface of the preform shape. Diamond may be deposited on the surface of a preform shape that is subsequently removed.

### BACKGROUND OF THE INVENTION

1. Field of the Invention

Embodiments of the present invention generally relate to a method of forming a polycrystalline diamond composite.

2. Description of the Related Art

Diamond is the hardest, stiffest and most wear resistant material available and also has the highest thermal conductivity. It is sought after for many industrial purposes, such as in cutting and drilling tools, for the management of heat in electronics and advanced semi-conductors. Natural gemstones are little used in these applications not only because of cost, but also because of the limited shapes that can be produced. Instead, a number of diamond materials and products have been developed. These materials include synthetic diamond particles, polycrystalline diamond (PCD) and chemically vapor deposited (CVD) diamond.

Synthetic diamond particles are made at extremely high pressures and temperatures that simulate the conditions under which diamonds form naturally such as the conditions described in U.S. Pat. No. 3,609,818. These particles have dimensions of generally a few microns up to about 1 mm. These diamonds are extensively used to make saw blades for cutting rock and concrete by bonding the particles with resins or metals onto a disc-shaped tool blank. Diamond particles are also extensively used for polishing and lapping. Synthetic diamond particles are also used to make polycrystalline diamond (PCD).

PCD is a synthesized intergrown mass of diamond particles produced by sintering diamond particles with metals at the same extremely high temperatures and pressures used to synthesize diamonds. U.S. Pat. No. 3,745,623 describes the formation of a mass of diamond crystals bonded to each other and to a supporting structure of cemented carbide. U.S. Pat. No. 4,224,380 describes an improvement in which the metal catalyst is largely leached away to give a porous body of bonded diamond particles. PCD is often produced as a disc that is then laser-cut into small shapes that are widely used for tipping cutting tools by brazing, or, as in the case of oil field tools, by infiltrating with liquid metals. The nature of the high temperature and high pressure process for making PCD limits the sizes and shapes that can be produced.

Patent Cooperation Treaty Patent Number 99/12866 and Patent Cooperation Treaty Patent Number 00/18702 describe a material in which a porous form of pressed diamond particles is heat treated at about atmospheric pressure to convert it into a diamond-silicon carbide composite. This material has several advantages over PCD, especially regarding the versatility of shapes and ready-to-use components that can be made, and features lower inherent manufacturing costs. One disadvantage arises in applications requiring the properties of a body made from 100 percent diamond.

Chemically vapor deposition (CVD) diamond is a polycrystalline diamond that is grown as a film with a thickness of a few microns on a substrate as described in U.S. Pat. No. 4,707,384. CVD diamond can also be produced as a freestanding sheet with a thickness of a few millimeters by deposition on a mandrel that is subsequently removed. Diamond does not easily wet or adhere to most materials, except carbide formers such as Si, SiC, Si₃N₄, WC, W, and Mo, which are commonly used as deposition materials for CVD diamond. There are a number of limitations associated with CVD such as the need for nucleation at the beginning of deposition and the build up of residual stress as the diamond films grow. The CVD process involves reacting selected gases together at or below atmospheric pressure so that the diamond product is deposited as an intergrown polycrystalline mass. The product typically has a growth texture characteristic of CVD processing. Diamond-like carbon is an amorphous carbon material with similar properties that can also be produced by vapor deposition such as the process described in U.S. Pat. No. 4,504,519. Physical vapor deposition (PVD) is also used for the formation of diamond films. As well as its use for cutting and wear tools, CVD diamond is used for certain specialized thermal management and optical applications. During the growth process it is also possible to introduce dopants such as boron which renders the diamond film to have semiconductor capabilities.

Vapor deposition and high pressure and temperature deposition methods have also been combined to produce useful components. For example, U.S. Pat. No. 5,624,068 describes a method for making tools that bonds a CVD or PVD diamond layer onto a cemented carbide body using high pressure and high temperature.

Comparing the properties of PCD, CVD diamond and natural diamond, those of CVD diamond and natural diamond are generally the most similar. Although CVD diamond avoids the traditional ultra high-pressure procedures, it is a slow, energy-intensive process and it is limited to thin, flat shapes.

Chemical vapor infiltration (CVI) is a process developed to make fiber-reinforced structural ceramic composites. The generally known CVI/CVD processes may be classified into four general categories: isothermal, thermal gradient, pressure gradient, and pulsed flow. See W. V. Kotlensky, Deposition of Pyrolytic Carbon in Porous Solids, 8 Chemistry and Physics of Carbon, 173, 190-203 (1973); W. J. Lackey, Review, Status, and Future of the Chemical Vapor Infiltration Process for Fabrication of Fiber-Reinforced Ceramic Composites, Ceram. Eng. Sci. Proc. 10[7-8] 577, 577-81 (1989). In principle, CVI uses a gas flow to permeate a fibrous preform and to deposit the selected ceramic matrix on the fibres to yield a composite component. The process has been mostly applied to the production of silicon carbide fiber-silicon carbide matrix composites. The technical problem with CVI is to achieve uniform penetration and growth of the matrix without closing off the pores. Initially this required very low deposition rates and process times of weeks or months. The last processing time can be shortened by processing in a temperature gradient such as the process described in U.S. Pat. No. 4,895,108, in which parts up to 5 inch by 2 inch outer diameter and wall thickness 0.25 inch have been produced with a processing time of 45 hours.

CVD on diamond preforms is described in U.S. Pat. Nos. 5,413,772 and 5,902675. A preform is produced by pouring slurry of diamond particles into a mould and evaporating the slurry vehicle. After treatment in a CVD reactor, diamond was found to have grown between the diamond particles, and the product had a density estimated to be approximately 63 percent dense.

Although a variety of materials and procedures have been developed to yield diamond products, these products are relatively expensive and there is a considerable limitation in the shapes and density combinations that can be produced. The present invention largely overcomes these limitations with a novel diamond-diamond composite of high diamond content and low porosity that can be prepared in a wide range of sizes and shapes.

### SUMMARY OF THE INVENTION

The present invention generally provides a method for forming polycrystalline diamond composites comprising forming a preform shape with at least 60 volume percent diamond, and then depositing diamond by chemical vapor methods within remaining pores. The chemical vapor methods may be chemical vapor infiltration or deposition with a thermal gradient applied through a thickness of the preform shape. The thermal gradient may be selected to provide sufficient to produce a diamond layer on a hot surface of the preform shape but is too low to produce a diamond layer on a cooler surface of the preform shape. The invention further provides for the use of high density diamond preforms as substrates for CVD diamond.

### DETAILED DESCRIPTION

To form a polycrystalline diamond composite a method utilizing vapor deposition and particularly chemical vapor deposition is selected. A mixture of diamond particles is formed into a green body or preform shape and set in a reactor. Diamond is deposited within the structure by vapor deposition. The vapor deposited diamond bonds the diamond particles together and fills up the pore spaces between the particles to yield a dense diamond-diamond composite body with an estimated 75 to 100 percent density.

The size and quality of diamond particles is selected depending on the end use of the material or component to be fabricated. Natural or synthetic diamond may be selected. Synthetic diamond particles are preferred. The diamond particles are between 1 and 500 microns in size. For thermal applications we prefer a majority of larger particles. For mechanical applications we prefer a majority of particles that are of an intermediate size. In every case we mix together lesser quantities of other particle sizes to give a mixture that when formed will yield at least 60 volume percent of diamond, preferably between 65 and 85 volume percent. The mixtures are designed so that the smaller particles fill some of the pore spaces between the larger particles. As required, additives are included in the diamond particle mixture. These additives comprise binders and/or dispersing agents and/or lubricants and can be polymeric materials and a suitable solvent. Examples of additives are polyethylene glycol (PEG), polyvinyl alcohol (PVA), and stearic acid. These additives may be used separately or in combination and can be applied in a suitable solvent, preferably water or alcohol. Other additives may be used. One purpose of the additives is to allow the formation of a shape with defined dimensions and contours. A further purpose is to give the resulting preform sufficient strength that it can be handled without damage. An additional purpose is to permit the attainment of high volume fractions of diamond particles in the preform.

Various processes are available for forming green shapes. These include, but are not limited to, uniaxial die pressing, isostatic pressing, injection moulding, slip casting, gel casting, and roll compaction. The type and quantity of the forming agent depends upon the process to form the green shape. In uniaxial die and isostatic pressing the quantity may be from 1 to 10 volume percent. In moulding, casting, and rolling methods, the volume fraction of forming agent can be up to 40 volume percent. The forming agent can be partially removed in a selected heating cycle or before the next stage of the process, or this removal can be accomplished in the subsequent reactor.

The diamond component of the green body or preform shape may be natural diamond, synthetic diamond, or a mixture of synthetic and natural. Both natural and synthetic diamond may have distinct crystalline shapes such as cubes, octahedra, cubo-octahedra, or others. The faces of these shapes are specific crystal planes. Diamond grows at different rates on different planes. Particle shapes that are bounded by faces that show the higher growth rates are preferred.

For example, to prepare a diamond green body or preform shape by uniaxial die pressing, at least 50 weight percent and less than 95 weight percent diamonds are mixed with more than 5 weight percent additives. The mixture of diamonds and additives is pressed in a die using a pressure of at least 100 MPa. Higher pressures increase the packing density of the diamonds leading to higher volume fractions of diamond in the preform and the desirable result of lower volume fractions of pores to be filled by the subsequent vapour deposition. This preform shape is heated to at least 300° C. to remove water and wholly or partially to remove additives. At this stage this treated preform shape can be machined to change contours or add additional features if required.

The treated preform shape is loaded into a suitable reactor for CVD/CVI of diamond. The reactor is operated to deposit diamond from the vapour onto the surfaces of the diamond particles in the preform. The reactor conditions are adjusted as the deposition occurs so that the surface pores are not closed off before deposition is accomplished on the diamond grains within the body or in this way the pore content of the product will be reduced. In this way the product will be essentially pore free and the diamond particles throughout the body will be bonded together by an interconnected layer of deposited diamond. These conditions can be met in several ways. In one way, a thermal gradient is applied through the thickness of the body and the reacting gases are caused to flow from the cooler side to the hotter side of the body. The temperatures are adjusted so that the rate of the chemical reaction is sufficient to produce the diamond layer on the hot side of the body but is too low to produce it on the cool side of the body. During the process the temperature conditions are adjusted to keep pace with the deposition front that is growing towards the cool side. In this way the majority of pores in the body are filled and the reaction is terminated when deposition has occurred on the original cool side. On completion of the CVD/CVI of diamond into the preform the deposition can be continued to produce a layer of CVD diamond on the surface of the product.

In another embodiment of the invention, high density diamond preforms are used as substrates for CVD diamond. After deposition, the preform substrate is removed by sandblasting or other machining to leave the freestanding CVD diamond film. The ideal form is one that is 100% diamond, has a high density, preferably at least 70%, with a controlled particle size, at least at the surface. The form should be sufficiently rigid to act as a substrate, but sufficiently soft that it can be removed by sandblasting or machining with conventional tools. This form is designed to minimize infiltration by CVD diamond. The finer particle size and smaller pores between particles has less likelihood of infiltration. Preforms are made using the methods described above. We select diamond sizes depending on the texture desired in the end product. The size and distribution of diamond particle sizes is controlled by mixing. In pressing and roll compaction methods we can choose to use high pressures that tend to crush the diamond at the surface, thereby altering the size at the surface. The diamonds in the substrate provide the nucleation points for CVD deposition and eliminate nucleation problems that are seen in other substrates. Roll compacted sheet can be of a range of thicknesses, including 0.5 mm, or even less if fine particles, e.g. 10 microns are used. The form undergoes the same binder burnout as described above to leave a small fraction of binder that keeps the sheet rigid and sufficiently strong so that it can be handled. The deposition will attach only to the outermost diamonds in the substrate. After deposition the substrate is removed by sandblasting or machining with simple tools.

The process has several advantages. For example, by using a diamond preform consisting of up to 80 volume percent diamond and as little as 20 volume percent pores, only the volume percent of pores needs to be filled to produce a body of the same volume as that produced by established CVD, leading to a comparative saving in time and cost of up to 80 percent. Compared to PCD, the process offers 100 percent polycrystalline diamond without metal impurities, the versatility in shape making that is lacking in the PCD process, and avoidance of the very high pressure and temperatures of the PCD process. A further advantage is that the diamond preforms can be complex shapes leading to 95 to 100 percent diamond components that will find application in a wide range of areas such as, but not limited to: electronics, optics, semiconductors, gemstones, aerospace, mining, drilling, and metal-working.

While the foregoing is directed to embodiments of the present invention, other and further embodiments of the invention may be devised without departing from the basic scope thereof, and the scope thereof is determined by the claims that follow.

1. A method for forming polycrystalline diamond composites, comprising:
forming a preform shape with at least 60 volume percent diamond; and then
depositing diamond by chemical vapor methods within remaining pores.

2. The method of claim 1, wherein the chemical vapor deposition is chemical vapor infiltration with a thermal gradient is applied through a thickness of the preform shape.

3. The method of claim 2, wherein the thermal gradient is sufficient to produce a diamond layer on a hot surface of the preform shape but is too low to produce a diamond layer on a cooler surface of the preform shape.

4. The method of claim 1, wherein forming the preform shape comprises pressing a mixture of diamonds and additives in a die using a pressure of at least 100 MPa.

5. The method of claim 4, wherein forming the preform shape further comprises heating the preform shape to at least about 300° C.

6. The method of claim 2, wherein the deposition is continued to produce a layer of diamond on the surface of the preform shape.

7. A method for forming polycrystalline diamond composites, comprising:
forming a preform shape with at least 60 volume percent diamond; and
depositing diamond by chemical vapor methods onto the surface of the perform shape.

8. The method of claim 7, wherein the preform shape is removed by sandblasting or other machining.
